(19) United States
(12) Patent Application Publication
(10) Pub. No.: US 2015/0144194 A1
(43) Pub. Date: May 28, 2015

(54) Solar Cell Protective Sheet and Solar Cell Module

(71) Applicant: Mitsubishi Rayon Co., Ltd., Tokyo (JP)

(72) Inventors: Taira Kajisa, Yokohama-shi (JP); Ayaka Kuwahara, Yokohama-shi (JP); Haruko Ootsuki, Yokohama-shi (JP); Fumiko Fujie, Otake-shi (JP); Yuhei Konokawa, Otake-shi (JP)

(73) Assignee: Mitsubishi Rayon Co., Ltd., Tokyo (JP)

(21) Appl. No.: 14/410,625

(22) PCT Filed: Jun. 28, 2013
(86) PCT No.: PCT/JP2013/067753

§ 371 Date: Dec. 23, 2014

(30) Foreign Application Priority Data
Jul. 3, 2012 (JP) 2012-149620
Sep. 19, 2012 (JP) 2012-205548

(51) Int. Cl. H01L 31/048; H01L 31/042; H01L 31/049

(52) U.S. Cl. CPC H01L 31/0481; H01L 31/049; H02S 20/00
USPC 136/259

(57) ABSTRACT

A solar cell module is provided with a solar cell, a sealing member embedding the solar cell therein, a front surface protective member, and a back surface protective member. The storage modulus of the sealing member for the temperature range of 20-40° C. is from 6×10⁷ Pa to 1×10⁹ Pa (inclusive), and the average linear expansion coefficient, which is the average of linear expansion coefficients in the length direction and in the width direction when the temperature of the back surface protective member is changed from 20° C. to 25° C., is 40 ppm/° C. or less. A solar cell protective sheet is a laminate wherein an adhesive layer contains a (meth)acrylic polymer including functional groups reactive with carboxyl groups is laminated on the surface of a transparent resin sheet formed from at least one light-transmitting resin material selected from (meth)acrylic resins, polycarbonate resins and fluororesins.

### TECHNICAL FIELD

The present invention relates to a solar cell protective sheet and a solar cell module.

### BACKGROUND ART

Known solar cell modules have a structure including a transparent front surface protective member disposed on the side on which sunlight is incident; a back surface protective member, for example, a white or black back surface protective member, disposed on the back side; and a transparent sealing member and a solar cell disposed between the members. In general, as the transparent front surface protective member disposed on the incidence plane side, tempered glass having high transmittance of sunlight and excellent mechanical strength is used.

In recent years, front surface protective members of transparent resin sheets have been investigated for weight reduction. For example, Patent Document 1 discloses a solar cell module including a back surface protective member of a glass epoxy substrate or a paper epoxy substrate having a thickness of 3 mm or more and 4 mm or less and a front surface protective member of at least one of an acrylic resin and a polycarbonate resin.

### CITATION LIST

### Patent Document

Patent Document 1: Japanese Unexamined Patent Application, Publication No. 2009-266958

### SUMMARY OF INVENTION

### Technical Problem

However, a front surface protective member made of tempered glass has a high specific gravity, compared to a front surface protective member made of a resin material, and therefore increases the mass of the solar cell module. In some of buildings in which such solar cell modules are installed, reinforcement is required. In addition, a vehicle on which a solar cell module including a front surface protective member made of tempered glass is mounted has a risk of increasing the fuel consumption and also has a risk of breaking the tempered glass by the vibration of the vehicle.

In the solar cell module disclosed in Patent Document 1, since the back surface protective member is a glass epoxy substrate or paper epoxy substrate having a thickness of 3 mm or more and 4 mm or less, notable weight reduction has not been achieved.

Furthermore, Patent Document 1 does not clearly describe the details of physical properties required in each member, such as the thickness of an acrylic resin or polycarbonate resin as the front surface protective member. The acrylic resin or polycarbonate resin used as the protective layer on the incidence plane side has a very high average linear expansion coefficient of 70 to 140 ppm/° C., whereas the glass epoxy substrate or paper epoxy substrate as examples of the back surface protective member has an average linear expansion coefficient of 10 to 40 ppm/° C. Therefore, there is a risk of causing a warp in the solar cell module during the production process if the average linear expansion coefficients and the thicknesses of the back surface protective member and the front surface protective member are not appropriately adjusted.

It is an object of the present invention to provide a solar cell module being lightweight, exhibiting excellent durability in a reliability test such as an impact resistance test, and capable of being produced at low cost.

### Solution to Problem

The above-mentioned problems can be solved by the following aspects [1] to [15]:

[1] A solar cell module comprising a solar cell, a sealing member embedding the solar cell therein, a front surface protective member, and a back surface protective member, wherein the sealing member has a storage modulus of 6×10⁷ Pa or more and 1×10⁹ Pa or less in a temperature range of 20° C. to 40° C.; and the back surface protective member has an average linear expansion coefficient of 40 ppm/° C. or less, wherein the average linear expansion coefficient is the mean value of linear expansion coefficients in the length direction and the width direction when the temperature of the back surface protective member is changed from 20° C. to 25° C.;

[2] The solar cell module according to Aspect [1], wherein the front surface protective member and the sealing member are laminated via an adhesive layer containing a (meth)acrylic polymer including functional groups reactive with carboxyl groups therebetween;

[3] The solar cell module according to Aspect [1], wherein the front surface protective member is a laminate composed of a transparent resin sheet made of at least one transparent resin material selected from (meth)acrylic resins, polycarbonate resins, and fluororesins and an adhesive layer comprising a (meth)acrylic polymer including functional groups reactive with carboxyl groups laminated on a surface of the transparent resin sheet;

[4] The solar cell module according to any one of Aspects [1] to [3], wherein the sealing member comprises a thermoplastic resin including an olefin unit and another copolymerizable monomer unit;

[5] The solar cell module according to Aspect [4], wherein the olefin unit is an ethylene unit;

[6] The solar cell module according to any one of Aspects [1] to [5], wherein the back surface protective member has a mass per unit area of 6 kg/m² or less;

[7] The solar cell module according to any one of Aspects [1] to [6], wherein the back surface protective member comprises a fiber-reinforced material;

[8] The solar cell module according to Aspect [7], wherein the fiber-reinforced material is glass cloth;

[9] The solar cell module according to any one of Aspects [1] to [8], wherein the back surface protective member comprises a binder resin;

[10] The solar cell module according to Aspect [9], wherein the binder resin is an epoxy resin;

[11] The solar cell module according to any one of Aspects [1] to [10], wherein the solar cell is disposed on the front surface protective member side than the neutral plane of the solar cell module;

[12] A solar cell protective sheet comprising a transparent resin sheet made of at least one transparent resin material selected from (meth)acrylic resins, polycarbonate resins, and fluororesins and an adhesive layer comprising a (meth)acrylic polymer including functional groups reactive with carboxyl groups laminated on a surface of the transparent resin sheet;

[13] The solar cell protective sheet according to Aspect [12], wherein the transparent resin sheet has a thickness of 0.03 mm or more and 0.6 mm or less;

[14] The solar cell protective sheet according to Aspect [12] or [13], wherein the (meth)acrylic polymer including functional groups reactive with carboxyl groups comprises 0.5 mol % or more and 30 mol % or less of a monomer unit including a functional group reactive with a carboxyl group based on 100 mol % of the monomer unit of the whole polymer in the adhesive layer; and

[15] A solar cell module comprising a solar cell protective sheet according to any one of Aspects [12] to [14], a sealing member mainly composed of at least one selected from ethylene-unsaturated carboxylic acid copolymers and ionomers of ethylene-unsaturated carboxylic acid copolymers on the front surface protective member side, a solar cell, a sealing member on the back surface protective member side, and a back surface protective member laminated in this order.

### Advantageous Effects of Invention

The solar cell module of the present invention is lightweight, is prevented from warping, exhibits excellent durability in a reliability test such as an impact resistance test, can be produced at low cost, and is suitable for various uses such as domestic use, on-vehicle use, and use in compact equipment.

### BRIEF DESCRIPTION OF DRAWINGS

FIG. 1 is a schematic cross-sectional view of an embodiment of the solar cell module of the present invention;

FIG. 2 is a schematic diagram illustrating the concept of a neutral plane in a solar cell module of the present invention;

FIG. 3 is a schematic cross-sectional view of a solar cell module having a solar cell disposed on the front surface protective member side than the neutral plane;

FIG. 4 is a schematic cross-sectional view of a solar cell module having a solar cell disposed on the back surface protective member side than the neutral plane;

FIG. 5 is a graph showing changes in storage module by changes of temperature of the sealing material; and

FIG. 6 is a diagram showing a laminate structure for preparing a test piece to be used in adhesiveness evaluation.

### DESCRIPTION OF EMBODIMENTS

The solar cell module of the present invention will now be described in detail. Throughout the specification, the term “(co)polymer” refers to at least one of “homopolymer” and “copolymer”. The term “(meth)acrylic” refers to at least one of “acrylic” and “methacrylic”. The term “(meth)acrylate” refers to at least one of “acrylate” and “methacrylate”.

[Solar Cell Module]

The solar cell module of the present invention includes a solar cell, a sealing member embedding the solar cell therein, a front surface protective member, and a back surface protective member. The sealing member has a storage modulus of 6×10⁷ Pa or more and 1×10⁹ Pa or less in a temperature range of 20° C. to 40° C. The back surface protective member has an average linear expansion coefficient of 40 ppm/° C. or less, wherein the average linear expansion coefficient is the mean value of linear expansion coefficients in the length direction and the width direction when the temperature of the back surface protective member is changed from 20° C. to 25° C. This solar cell module has a structure composed of the front surface protective member, the sealing member embedding the solar cell therein, and the back surface protective member laminated in this order.

In the solar cell module of the present invention, from the viewpoint of enhancing the adhesion between the front surface protective member and the sealing member, the front surface protective member and the sealing member are preferably laminated via an adhesive layer containing a (meth)acrylic polymer including functional groups reactive with carboxyl groups.

In the solar cell module of the present invention, from the viewpoint of imparting excellent transparency to the front surface protective member and the viewpoint of enhancing the adhesion between the front surface protective member and the sealing member, the front surface protective member is preferably a laminate composed of a transparent resin sheet made of at least one transparent resin material selected from (meth)acrylic resins, polycarbonate resins, and fluororesins and an adhesive layer containing a (meth)acrylic polymer including functional groups reactive with carboxyl groups laminated on a surface of the transparent resin sheet.

FIG. 1 is a diagram schematically illustrating a cross-section of a solar cell module according to an embodiment of the present invention. As shown in FIG. 1, the solar cell module 10 is constituted of a front surface protective member 11, a sealing member 14 on the front surface protective member side, a solar cell 16, a sealing member 15 on the back surface protective member side, a back surface protective member 17, and an electrode material 18. The front surface protective member 11 is, for example, a laminate of a transparent resin sheet 12 and an adhesive layer 13.

Specifically, the front surface protective member 11 is disposed on the light-receiving surface side (front face side) on which sunlight is incident, and the back surface protective member 17 is disposed on the surface (back face side) facing the light-receiving surface side. Between the front surface protective member 11 and the back surface protective member 17, the sealing member 14 on the front surface protective member side, the solar cell 16, and the sealing member 15 on the back surface protective member side are laminated in this order from the light-receiving surface side. The electrode material 18 is connectable to the outside of the solar cell module.

### [Solar Cell]

The solar cell may be any cell that can generate electricity using a photovoltaic effect of a semiconductor and can be a conventionally known one. The solar cell is preferably a crystal silicon-based cell from the viewpoint of balance between the power generation performance and the manufacturing cost. The solar cell can also be, for example, a cell in a wiring form, as shown in FIG. 1, in which the wiring member extends to both front and back surfaces of the cell.

### [Sealing Member]

The sealing member is a member embedding the solar cell therein. The sealing member has a storage modulus of 6×10⁷ Pa or more and 1×10⁹ Pa or less in a temperature range of 20° C. to 40° C. The sealing member is preferably a transparent resin that can seal the solar cell and has insulation. The sealing member preferably has a total light transmittance of 85% or more, more preferably 90% or more, from the viewpoint of increasing the utilization efficiency of sunlight. Since the sealing member has a storage modulus of 6×10⁷ Pa or more and 1×10⁹ Pa or less in a temperature range of 20° C. to 40° C., the solar cell module has high impact resistance.

Examples of the sealing material constituting the sealing member include thermoplastic resins including olefin units and other copolymerizable monomer units. Examples of the olefin unit include ethylene units. Specific examples of the sealing material include ethylene-vinyl ester copolymers such as an ethylene-vinyl acetate copolymer; ethylene-unsaturated carboxylic acid ester copolymers such as an ethylene-methyl (meth)acrylate copolymer, an ethylene-ethyl (meth)acrylate copolymer, an ethylene-isobutyl (meth)acrylate copolymer, and an ethylene-n-butyl (meth)acrylate copolymer; ethylene-unsaturated carboxylic acid copolymers such as an ethylene-(meth)acrylic acid copolymer and an ethylene-isobutyl (meth)acrylate-(meth)acrylic acid copolymer, and their ionomers; and low-density poly ethylene.

Among these copolymers, preferred are an ethylene-vinyl acetate copolymer, an ethylene-unsaturated carboxylic acid ester copolymer, and low-density polyethylene.

The sealing member can be, for example, in a sheet form or a liquid form.

The sealing member is, for example, in a sheet having a thickness of 0.2 mm or more and 1.0 mm or less.

In the present invention, in order to enhance the adhesion between the front surface protective member and the sealing member on the front surface protective member side, the front surface protective member 11 and the sealing member 14 on the front surface protective member side are preferably laminated via an “adhesive layer” containing a (meth)acrylic polymer including functional groups reactive with carboxyl groups. In such a case, the sealing member on the front surface protective member side is, for example, mainly composed of at least one selected from ethylene-unsaturated carboxylic acid copolymers and ionomers of ethylene-unsaturated carboxylic acid copolymers. The “adhesive layer” will be described later.

Examples of the unsaturated carboxylic acid as the raw material of the ethylene-unsaturated carboxylic acid copolymer include (meth)acrylic acid, maleic acid, and itaconic acid. Examples of the ion source for the ionomer of the ethylene-unsaturated carboxylic acid copolymer include alkali metals such as lithium, sodium, and potassium; alkali earth metals such as magnesium and calcium; and zinc. In the ionomer of the ethylene-unsaturated carboxylic acid copolymer, the degree of neutralization of the unsaturated carboxylic acid unit with the ion source is preferably 90% or less and more preferably 10% to 85%.

The sealing member on the front surface protective member side preferably has a storage modulus of 1×10⁵ Pa or more at 80° C. and a total light transmittance of 80% or more in a wavelength range of 400 to 800 nm, from the viewpoint of preventing deformation and flow of the sealing member at high temperature and from the viewpoint of increasing the utilization efficiency of sunlight.

In the present invention, the material of the sealing member 15 on the back surface protective member side may be the same as or different from that of the sealing member 14 on the front surface protective member side and can be appropriately selected depending on the purpose.

### [Front Surface Protective Member]

The front surface protective member is a protective member laminated on a surface of the sealing member on the side on which sunlight is incident in the solar cell module of the present invention. The front surface protective member prevents the sealing member layer from being exposed by scratches when the solar cell module is installed and has a role of preventing a short circuit of the solar cell module. The front surface protective member also has a role of imparting weather resistance to the solar cell module for withstanding use in the field for a long time and a role as a barrier for sealing the solar cell from, for example, moisture and oxygen from the outside.

Examples of the front surface protective member include transparent resin sheets prepared from transparent resin materials. The transparent resin sheet may be any type of sheet having a high total light transmittance. The front surface protective member preferably has a total light transmittance of 85% or more, more preferably 90% or more, in a wavelength range of 400 to 800 nm from the viewpoint of increasing the utilization efficiency of sunlight.

Examples of the transparent resin material include (meth)acrylic resins, fluororesins, polycarbonate resins, polyester resins such as polyethylene terephthalate and polyethylene naphthalate, styrene resins, cellulose resins, acrylonitrile-butadiene-styrene copolymers, olefin resins, polyamide resins, vinyl chloride resins, and polymethacrylimide resins. Among the above-mentioned materials, from the viewpoint of translucency or from the viewpoint of weather resistance, the front surface protective member is preferably a transparent resin sheet made of at least one transparent resin material selected from (meth)acrylic resins, polycarbonate resins, and fluororesins.

Specific examples of the (meth)acrylic resin, polycarbonate resin, and fluororesin include (co)polymers including one or more of the following monomer units: (meth)acrylate monomers such as methyl (meth)acrylate, ethyl (meth)acrylate, propyl (meth)acrylate, n-butyl (meth)acrylate, i-butyl (meth)acrylate, s-butyl (meth)acrylate, t-butyl (meth)acrylate, 2-ethylhexyl (meth)acrylate, lauryl (meth)acrylate, tridecyl (meth)acrylate, stearyl (meth)acrylate, cyclohexyl (meth)acrylate, benzyl (meth)acrylate, phenoxyethyl (meth)acrylate, isobornyl (meth)acrylate, glycidyl (meth)acrylate, tetrahydrofurfuryl (meth)acrylate, allyl (meth)acrylate, 2-hydroxyethyl (meth)acrylate, hydroxypropyl (meth)acrylate, 2-methoxyethyl (meth)acrylate, and 2-ethoxyethyl (meth)acrylate; fluorinated (meth)acrylate monomers such as 2,2,2-trifluoroethyl (meth)acrylate, 1,1,2,2-tetrafluoroethyl (meth)acrylate, and 2,2,3,3,4,4,5,5-octafluoropentyl (meth)acrylate; fluorocarbon monomers such as vinylidene fluoride; bifunctional monomers such as ethylene glycol di(meth)acrylate, tripropylene glycol di(meth)acrylate, isocyanuric acid ethylene oxide-modified di(meth)acrylate, triethylene glycol di(meth)acrylate, diethylene glycol di(meth)acrylate, neopentyl glycol di(meth)acrylate, 1,6-hexanediol di(meth)acrylate, 1,5-pentanediol di(meth)acrylate, 1,3-butylene glycol di(meth)acrylate, polybutylene glycol di(meth)acrylate, 2,2-bis(4-(meth)acryloxypolyethoxyphenyl)propane, 2,2-bis(4-(meth)acryloxyethoxyphenyl)propane, 2,2-bis(4-(3-(meth)acryloxy-2-hydroxypropoxy)phenyl)propane, 1,2-bis(3-(meth)acryloxy-2-hydroxypropoxy)ethane, 1,4-bis(3-(meth)acryloxy-2-hydroxypropoxy)butane, dimethyloltricyclodecane di(meth)acrylate, bisphenol A ethylene oxide adduct di(meth)acrylate, bisphenol A propylene oxide adduct di(meth)acrylate, hydroxypivalic acid neopentyl glycol di(meth)acrylate, divinylbenzene, and methylene bisacrylamide; trifunctional monomers such as pentaerythritol tri(meth)acrylate, trimethylolpropane tri(meth)acrylate, trimethylolpropane ethylene oxide-modified tri(meth)acrylate, trimethylolpropane propylene oxide-modified triacrylate, and isocyanuric acid ethylene oxide-modified tri(meth)acrylate; condensation reaction mixtures of succinic acid, trimethylolethane, and acrylic acid; tetra- or higher functional monomers such as dipentaerythritol hexa(meth)acrylate, dipentaerythritol penta(meth)acrylate, ditrimethylolpropane tetraacrylate, and tetramethylolmethane tetra(meth)acrylate; di- or higher functional urethane acrylates; and di- or higher functional polyester acrylates.

The transparent resin sheet as the front surface protective member preferably has a thickness of 0.03 mm or more and 0.6 mm or less. A transparent resin sheet having a thickness of 0.03 mm or more tends to be prevented from wrinkling when the transparent resin sheet is laminated on a surface of the sealing member layer and tends to be able to prevent the sealing member layer from being exposed by scratches, for example, when the solar cell module of the present invention is installed. In addition, a transparent resin sheet having a thickness of 0.03 mm or more tends to increase the heat resistance and high-temperature and high-humidity resistance of the transparent resin sheet and tends to prevent the surface of the solar cell module from cracking. A transparent resin sheet having a thickness of 0.6 mm or less tends to prevent the mass of the solar cell module from increasing and tends to prevent the solar cell from cracking and prevent the electrode material from being deformed and disconnected. The upper limit of the thickness of the transparent resin sheet is more preferably 0.2 mm or less.

The transparent resin sheet can contain a fiber-reinforced material of an organic material or an inorganic material, such as glass, within a range that does not reduce the total light transmittance of the front surface protective member. Examples of the form of the fiber-reinforced material include unidirectional materials, cloths, non-woven fabrics, wool, mats, and short fibers (cut fibers and milled fibers). These forms may be employed alone or in combination of two or more thereof.

The transparent resin sheet may have a monolayer structure or a multilayer structure composed of two or more layers. The composition of the transparent resin material constituting the transparent resin sheet may stepwisely vary in the thickness direction. For example, when the transparent resin sheet has a multilayer structure including a fluorine-based resin layer as a surface layer, the characteristics of a fluororesin, i.e., weather resistance and antifouling property, can be provided. The multilayer structure may be formed by, for example, co-extrusion.

The front surface protective member can contain a rubber-based polymer. Examples of the rubber-based polymer include multi-stage polymers so-called core-shell type polymers, which are each produced by preparing a polymer for forming a rubber layer (core) and then preparing a polymer for forming a graft layer (shell).

The polymer for a rubber layer can be a single stage polymer or a multi-stage polymer. The polymer for a rubber layer preferably has a glass transition temperature (hereinafter, referred to as “Tg”) of 25° C. or less. In the present invention, Tg is a temperature measured in accordance with JIS K7121. The rubber layer can be formed by preparing a polymer for the rubber layer in the presence of hard polymer particles having a Tg of higher than 25° C. depending on the purpose.

Examples of the type of rubber component forming the rubber layer include rubbers prepared by polymerizing the following monomers: alkyl (meth)acrylate-based monomers, silicone-based monomers, styrene-based monomers, nitrile-based monomers, conjugated diene-based monomers, urethane bond-forming monomers, ethylene-based monomers, propylene-based monomers, and isobutene-based monomers.

The rubber-based polymer constituting the rubber layer may have a cross-linking bond formed by a cross-linking agent. Between the rubber-based polymer constituting the rubber layer and the polymer constituting a layer adjoining the rubber layer, a chemical bond by a cross-linking agent may be formed. The rubber-based polymer may have a laminate structure composed of three or more layers.

Examples of the polymer contained in the rubber layer include (co)polymers produced from the following monomers: alkyl (meth)acrylates in which the alkyl group has 1 to 8 carbon atoms, such as methyl (meth)acrylate, ethyl (meth)acrylate, propyl (meth)acrylate, n-butyl (meth)acrylate, i-butyl (meth)acrylate, s-butyl (meth)acrylate, t-butyl (meth)acrylate, 2-ethylhexyl (meth)acrylate, and cyclohexyl (meth)acrylate; styrene; and acrylonitrile.

Examples of the cross-linking agent include alkylene glycol di(meth)acrylates such as ethylene glycol di(meth)acrylate, 1,3-butylene glycol di(meth)acrylate, 1,4-butylene glycol di(meth)acrylate, and propylene glycol di(meth)acrylate; and allyl (meth)acrylate, diallyl phthalate, triallyl cyanurate, triallyl isocyanurate, divinylbenzene, diallyl maleate, trimethylolpropane tri(meth)acrylate, and allyl cinnamate. These cross-linking agents may be used alone or in combination of two or more thereof.

Examples of the monomer used for producing the polymer for forming a graft layer include alkyl (meth)acrylates in which the alkyl group has 1 to 8 carbon atoms, such as methyl (meth)acrylate, ethyl (meth)acrylate, propyl (meth)acrylate, n-butyl (meth)acrylate, i-butyl (meth)acrylate, s-butyl (meth)acrylate, t-butyl (meth)acrylate, and 2-ethylhexyl (meth)acrylate; cycloalkyl (meth)acrylates in which the cycloalkyl group has 3 to 8 carbon atoms, such as cyclohexyl (meth)acrylate; aromatic vinyl compounds such as styrene; and vinyl cyanides such as acrylonitrile. These monomers may be used alone or in combination of two or more thereof.

The polymer for forming a graft layer (shell) preferably has a glass transition temperature, Tg, higher than that of the polymer for a rubber layer (core). For example, the Tg of the polymer for a rubber layer is −50° C. to 20° C., and the Tg of the polymer for forming a graft layer is 50° C. to 100° C.

In the present invention, the front surface protective member can contain a light-resistant stabilizer such as an ultraviolet absorber or a light stabilizer. Examples of the ultraviolet absorber include salicylic acid compounds, benzophenone compounds, and cyanoacrylate compounds. These ultraviolet absorbers may be used alone or in combination of two or more thereof. Examples of the light stabilizer include hindered amine-based light stabilizers such as bis(2,2,6,6-tetramethyl-4-piperidyl)sebacate. These light stabilizers may be used alone or in combination of two or more thereof.

The front surface protective member can optionally contain various additives such as a flame retardant, a plasticizer, an antistatic agent, a mold release agent, a dye, a pigment, a heat resistance improver, a crystal nucleating agent, a flowability-improving agent, a conductivity-improving agent, a surfactant, a compatibilizing agent, an antifog agent, a foaming agent, an antibiotic, or a fluorescent agent.

The front surface protective member can be subjected to surface treatment such as plasma treatment, corona treatment, or application of a coating material, for imparting antifouling performance and abrasion resistance to the surface and further for preventing, for example, adhesion to the sealing member layer.

In the present invention, the sealing member and the front surface protective member are preferably laminated via an adhesive layer containing a (meth)acrylic polymer including functional groups reactive with carboxyl groups.

### [Adhesive Layer]

The adhesive layer has a role of bonding the front surface protective member and the sealing member in the solar cell module. The adhesive layer is, for example, a layer containing a (meth)acrylic polymer including functional groups reactive with carboxyl groups (hereinafter, may be referred to as “(meth)acrylic polymer B for the adhesive layer” or “polymer B”).

The adhesive layer can be in a form of, for example, an adhesive film or an adhesive sheet and can be used as a member different from the front surface protective member. In the solar cell module of the present invention, the front surface protective member and the sealing member are bonded to each other via an adhesive layer such as this adhesive film. The adhesive layer can be used as a laminate composed of the adhesive layer and a transparent resin sheet. In the present invention, this laminate is called “front surface protective member with an adhesive layer” or “solar cell protective sheet”.

The (meth)acrylic polymer B for the adhesive layer contains, for example, 50 mass % or more of (meth)acrylate monomer units. Examples of the functional group reactive with a carboxyl group include a glycidyl group, an oxazoline group, and an isocyanate group. The polymer B can include at least one type of functional groups reactive with carboxyl groups.

Examples of the (meth)acrylic polymer B for the adhesive layer include (co)polymers including a monomer unit including a glycidyl group, a monomer unit including an oxazoline group, or a monomer unit including an isocyanate group; copolymers composed of at least one of these monomer units and another monomer unit; and mixtures of at least two selected from these (co)polymers. The polymer B can be prepared by polymerizing a monomer including a functional group reactive with a carboxyl group (hereinafter, may be referred to as “(meth)acrylic monomer b for an adhesive layer” or “monomer b”) or by polymerizing a monomer mixture of the monomer b and another monomer.

Examples of the monomer including a glycidyl group include unsaturated carboxylic acid esters such as glycidyl(meth)acrylate, glycidylethyl (meth)acrylate, and glycidyl itaconate; and unsaturated glycidyl ethers such as allylglycidyl ether, 2-methylallylglycidyl ether, and styrene-p-glycidyl ether. These monomers may be used alone or in combination of two or more thereof. Among these monomers, glycidyl (meth)acrylate is preferred in the light of reactivity.

Examples of the monomer including an oxazoline group include 2-vinyl-2-oxazoline, 2-vinyl-4-methyl-2-oxazoline, 2-vinyl-5-methyl-2-oxazoline, 2-isopropenyl-2-oxazoline, 2-isopropenyl-4-methyl-2-oxazoline, and 2-isopropenyl-5-ethyl-2-oxazoline. These monomers may be used alone or in combination of two or more thereof. Among these monomers, 2-isopropenyl-2-oxazoline is industrially easily available and is preferred.

Examples of the monomer including an isocyanate group include aromatic diisocyanates such as 2,4-tolylene diisocyanate, 2,6-tolylene diisocyanate, xylene-1,4-diisocyanate, xylene-1,3-diisocyanate, tetramethylxylene diisocyanate, 4,4′-diphenylmethane diisocyanate, 2,4′-diphenylmethane diisocyanate, 2,2′-diphenylmethane diisocyanate, 4,4′-diphenyl ether diisocyanate, 2-nitrodiphenyl-4,4′-diisocyanate, 2,2′-diphenylpropane-4,4′-diisocyanate, 3,3′-dimethyldiphenylmethane-4,4′-diisocyanate, 4,4′-diphenylpropane diisocyanate, m-phenylene diisocyanate, p-phenylene diisocyanate, naphthylene-1,4-diisocyanate, naphthylene-1,5-diisocyanate, and 3,3′-dimethoxydiphenyl-4,4′-diisocyanate; aliphatic diisocyanates such as tetramethylene diisocyanate, hexamethylene diisocyanate, decamethylene diisocyanate, and lysine diisocyanate; and alicyclic diisocyanates such as isophorone diisocyanate, hydrogenated tolylene diisocyanate, hydrogenated xylene diisocyanate, hydrogenated diphenylmethane diisocyanate, and hydrogenated tetramethylxylene diisocyanate. These monomers may be used alone or in combination of two or more thereof.

Examples other monomers include unsaturated carboxylic acids such as (meth)acrylic acid, maleic acid, and itaconic acid; (meth)acrylates such as methyl (meth)acrylate, ethyl (meth)acrylate, propyl (meth)acrylate, n-butyl (meth)acrylate, i-butyl (meth)acrylate, s-butyl (meth)acrylate, t-butyl (meth)acrylate, 2-ethylhexyl (meth)acrylate, lauryl (meth)acrylate, tridecyl (meth)acrylate, stearyl (meth)acrylate, cyclohexyl (meth)acrylate, benzyl (meth)acrylate, phenoxyethyl (meth)acrylate, isobornyl (meth)acrylate, glycidyl (meth)acrylate, tetrahydrofurfuryl (meth)acrylate, allyl (meth)acrylate, 2-hydroxyethyl (meth)acrylate, hydroxypropyl (meth)acrylate, 2-methoxyethyl (meth)acrylate, and 2-ethoxyethyl (meth)acrylate; maleimide derivatives such as N-phenylmaleimide, N-cyclohexylmaleimide, and N-t-butylmaleimide; unsaturated nitriles such as (meth)acrylonitrile; vinyl ethers such as methylvinyl ether and ethylvinyl ether; and olefins such as ethylene and propylene. These monomers may be used alone or in combination of two or more thereof.

The (meth)acrylic polymer B for the adhesive layer can be produced by known polymerization. In the present invention, for example, suspension polymerization can be employed. The suspension polymerization is preferably performed in the presence of a chain transfer agent. Examples of the chain transfer agent include primary or secondary mercapto compounds. The use of the primary or secondary mercapto compound provides good appearance or initial gloss to the resulting adhesive layer.

Examples of the primary or secondary mercapto compound include alkyl mercaptans such as n-butyl mercaptan, s-butyl mercaptan, n-octyl mercaptan, n-dodecyl mercaptan, and n-octadecyl mercaptan; thioglycolic acid esters such as 2-ethylhexyl thioglycolate, methoxybutyl thioglycolate, and trimethylolpropane tris(thioglycolate); and mercaptopropionic acid esters such as 2-ethylhexyl β-mercaptopropionate, 3-methoxybutyl β-mercaptopropionate, and trimethylolpropane tris(β-thiopropionate). These compounds may be used alone or in combination of two or more thereof. Among these compounds, preferred are n-octyl mercaptan, n-dodecyl mercaptan, and 2-ethylhexyl thioglycolate, which have large chain-transfer constants.

The amount of the primary or secondary mercapto compound is, for example, 0.1 parts by mass or more and 10 parts by mass or less based on 100 parts by mass of monomers that are used as raw materials of the (meth)acrylic polymer including functional groups reactive with carboxyl groups.

In production of (meth)acrylic polymer B for the adhesive layer by suspension polymerization, for example, an aqueous suspension containing a monomer b as a raw material of the polymer B, a dispersant, a polymerization initiator, and a chain transfer agent is heated for polymerization to give a suspension including the polymer B. Subsequently, the suspension is filtered, washed, and dehydrated, and the residue is dried. As a result, granular polymer B can be easily prepared.

In general, a granular (meth)acrylic polymer produced by suspension polymerization has a mass average particle diameter of about 10 to 2,000 μm and is a primary particle formed as a substantially complete sphere. In contrast, a granular (meth)acrylic polymer produced by emulsion polymerization and then subjected to aggregation or spray drying is generally an agglomerate having a mass average particle diameter of about 0.01 to 1 μm. Polymer particles formed by pulverizing a lump of a polymer produced by block polymerization or a lump of a polymer produced by solution polymerization and desolventization have various shapes and a broad particle size distribution.

The (meth)acrylic polymer B for the adhesive layer prepared by suspension polymerization preferably has a mass average particle diameter of 30 μm or more and 500 μm or less. When the polymer B has a mass average particle diameter of 30 μm or more, the scattering of fine powder into the atmosphere is low, the work environment is prevented from being polluted during the production process, and dust explosion is prevented. Furthermore, the fluidity of the particles is high to show high handleability. A polymer B having a mass average particle diameter of 500 μm or less has high dispersion stability of the polymer particles during the suspension polymerization. The polymer B more preferably has a mass average particle diameter of 80 μm or more and 300 μm or less.

Examples of the dispersant used in suspension polymerization for producing the (meth)acrylic polymer B for the adhesive layer include alkali metal salts of poly(meth)acrylic acid, copolymers of alkali metal salts of (meth)acrylic acid and (meth)acrylic acid esters, copolymers of alkali metal salts of sulfoalkyl (meth)acrylic acid and (meth)acrylic acid esters, alkali metal salts of polystyrenesulfonic acid, copolymers of alkali metal salts of styrenesulfonic acid and (meth)acrylic acid esters, polyvinyl alcohols having a degree of saponification of 70 to 100 mol %, and methyl cellulose. These dispersants may be used alone or in combination of two or more thereof. Among these dispersants, preferred are copolymers of alkali metal salts of sulfoalkyl(meth)acrylic acid and (meth)acrylic acid esters, because of their high dispersion stability during suspension polymerization.

The content of the dispersant in the aqueous suspension is preferably 0.002 mass % or more and 5 mass % or less. A dispersant content of 0.002 mass % or more provides high dispersion stability during the suspension polymerization. When the content of the dispersant is 5 mass % or less, the resulting polymer can be easily washed, dehydrated, and dried, and the polymer particles have high fluidity. The content of the dispersant is more preferably 0.01 mass % or more and 1 mass % or less. In addition, the aqueous suspension may contain an electrolyte such as sodium carbonate, sodium sulfate, or manganese sulfate, in order to improve the dispersion stability during the suspension polymerization.

The polymerization temperature of the suspension polymerization is preferably 30° C. or higher and 130° C. or lower. When the polymerization temperature is 30° C. or higher, the polymer can be produced in a relatively short period of time. When the polymerization temperature is 130° C. or lower, the dispersion stability during the suspension polymerization is high. The polymerization temperature of the suspension polymerization is more preferably 50° C. or higher and 100° C. or lower.

Examples of the polymerization initiator used in the suspension polymerization include azo compounds such as 2,2′-azobisisobutyronitrile, 2,2′-azobis(2-methylbutyronitrile), and 2,2′-azobis(2,4-dimethylvaleronitrile); organic peroxides such as lauroyl peroxide, stearoyl peroxide, benzoyl peroxide, bis(4-t-butylcyclohexyl)peroxy dicarbonate, 1,1,3,3-tetramethylbutylperoxy 2-ethylhexanoate, t-hexylperoxy 2-ethylhexanoate, t-butylperoxy 2-ethylhexanoate, t-hexylperoxyisopropyl monocarbonate, and t-butylperoxyisopropyl monocarbonate; and inorganic peroxides such as hydrogen peroxide, sodium persulfate, and ammonium persulfate. These polymerization initiators may be used alone or in combination of two or more thereof.

The amount of the polymerization initiator is preferably 0.05 parts by mass or more and 10 parts by mass or less based on 100 parts by mass of the raw material monomer. When the amount of the polymerization initiator is 0.05 parts by mass or more, the rate of polymerization of the raw material monomer is high to give the polymer in a relatively short period of time. When the amount of the polymerization initiator is 10 parts by mass or less, the generation of heat during polymerization is moderated, and the polymerization temperature can be easily controlled. The amount of the polymerization initiator is more preferably 0.1 parts by mass or more and 5 parts by mass or less.

The adhesive layer can optionally contain a binder resin, in addition to the (meth)acrylic polymer B for the adhesive layer.

Examples of the monomer as the raw material of the binder resin include unsaturated carboxylic acids such as (meth)acrylic acid, maleic acid, and itaconic acid; (meth)acrylates such as methyl (meth)acrylate, ethyl (meth)acrylate, propyl (meth)acrylate, n-butyl (meth)acrylate, i-butyl (meth)acrylate, s-butyl (meth)acrylate, t-butyl (meth)acrylate, 2-ethylhexyl (meth)acrylate, lauryl (meth)acrylate, tridecyl (meth)acrylate, stearyl (meth)acrylate, cyclohexyl (meth)acrylate, benzyl (meth)acrylate, phenoxyethyl (meth)acrylate, isobornyl (meth)acrylate, glycidyl (meth)acrylate, tetrahydrofurfuryl (meth)acrylate, allyl (meth)acrylate, 2-hydroxyethyl (meth)acrylate, hydroxypropyl (meth)acrylate, 2-methoxyethyl (meth)acrylate, and 2-ethoxyethyl (meth)acrylate; aromatic vinyl monomers such as styrene, α-methylstyrene, and vinyltoluene; and unsaturated nitriles such as (meth)acrylonitrile. These monomers may be used alone or in combination of two or more thereof.

The (meth)acrylic polymer B for the adhesive layer preferably has a mass average molecular weight (hereinafter, referred to as “Mw”) of 20,000 or more and 60,000 or less. When the polymer B has an Mw of 20,000 or less, a binder resin, compatible to the polymer B, having an Mw or 60,000 or more and a Tg of 55° C. or higher is preferably added to the polymer B, from the viewpoint of improving the coating properties of a polymer solution for an adhesive layer described below and of preventing destruction of aggregation of the adhesive layer.

The content of the monomer unit including a functional group reactive with a carboxyl group in the polymer B is preferably 0.5 mol % or more and 30 mol % or less based on 100 mol % of the monomer unit of the whole polymer in the adhesive layer. The adhesion between the front surface protective member and the sealing member can be improved by controlling the content of the monomer unit to 0.5 mol % or more and 30 mol % or less. The upper limit of the content of the monomer unit is more preferably 20 mol % or less and most preferably 10 mol % or less.

The adhesive layer preferably has a thickness of 0.1 to 20 μm, more preferably 1 to 10 μm, from the viewpoint of work efficiency in manufacturing of the solar cell module of the present invention and of reducing the manufacturing cost.

### [Solar Cell Protective Sheet]

The solar cell protective sheet of the present invention is a laminate composed of a transparent resin sheet made of at least one transparent resin material selected from (meth)acrylic resins, polycarbonate resins, and fluororesins and an adhesive layer containing the (meth)acrylic polymer B for the adhesive layer laminated on a surface of the transparent resin sheet.

The method for laminating the adhesive layer on a surface of the transparent resin sheet involves, for example, applying a (meth)acrylic polymer solution for an adhesive layer prepared by dissolving the (meth)acrylic polymer B for the adhesive layer in a diluent solvent to the surface of the transparent resin sheet and then volatilizing the diluent solvent to give an adhesive layer. Hereinafter, the (meth)acrylic polymer solution for an adhesive layer may be referred to as “polymer solution B′”.

The polymer solution B′ preferably has a viscosity of 40 mPa·s or less at 25° C. A polymer solution B′ having a viscosity of 40 mPa·s or less has good coating properties and can give a uniform adhesive layer. In addition, from the viewpoint of drying efficiency of the coating film made from the polymer solution B′, the viscosity of the polymer solution B′ is preferably 10 mPa·s or more.

Examples of the diluent solvent include aromatic solvents such as toluene, xylene, and benzene; alcohol solvents such as methanol, ethanol, isopropanol, isopropyl alcohol, n-butanol, and 2-butanol; and dimethylformamide, dimethylsulfoxide, dioxane, cyclohexanone, tetrahydrofuran, methyl ethyl ketone (MEK), acetone, diethyl ether, ethyl acetate, methyl acetate, chloroform, ethylene chloride, and methylene chloride. These diluent solvents may be used alone or in combination of two or more thereof.

Examples of the method of applying the polymer solution B′ to a surface of the transparent resin sheet include a reverse roll coating method, a gravure coating method, a kiss coating method, a die coater method, a roll brush method, a spray coating method, an air knife coating method, a wire bar coating method, a pipe doctor method, an impregnation coating method, and a curtain coating method.

The amount of the polymer solution B′ applied to a surface of the transparent resin sheet is preferably 1 to 10 g/m². The coating film of the polymer solution B′ preferably has a thickness of 0.1 to 30 μm and more preferably 0.5 to 15 μm. The volatilization of the diluent solvent from the coating film of the polymer solution B′ formed on the surface of the transparent resin sheet is performed by, for example, drying by heating with an oven.

### [Back Surface Protective Member]

In the present invention, the back surface protective member is a sheet having an average linear expansion coefficient of 40 ppm/° C. or less. The average linear expansion coefficient is the mean value of linear expansion coefficients in the length direction and the width direction when the temperature of the back surface protective member is changed from 20° C. to 25° C. Since the back surface protective member has an average linear expansion coefficient of 40 ppm/° C. or less, the solar cell module is prevented from warping, and it is possible to prevent cracking of the solar cell in a temperature cycling test or a dewing and freezing test and the deformation or disconnection of the wiring material. The average linear expansion coefficient is preferably 35 ppm/° C. or less. A back surface protective member having an average linear expansion coefficient of 1 ppm/° C. or more is preferred because of the easy availability of the raw material.

The mass per unit area of the back surface protective member is preferably 6 kg/m² or less, more preferably 5.6 kg/m² or less, and most preferably 5.2 kg/m² or less, from the viewpoint of reducing the weight of the solar cell module of the present invention. The term “unit area” refers to the unit area in a plane of the back surface protective member.

The back surface protective member preferably has a thickness of 6 mm or less. The weight of the solar cell module can be reduced by regulating the thickness of the back surface protective member to 6 mm or less. The thickness of the back surface protective member is preferably 0.2 mm or more from the viewpoint of achieving the protective function.

The back surface protective member can be a molded product containing a binder resin. Examples of the binder resin include thermosetting resins such as epoxy resins, polyamide resins, phenol resins, and saturated polyester; and thermoplastic resins such as acrylic resin.

The back surface protective member can be a molded product containing a fiber-reinforced material. An embodiment of such a molded product is, for example, a conjugated compound composed of a fiber-reinforced material and a binder resin or a sheet formed by compression molding of a fiber-reinforced material.

Examples of the form of the fiber-reinforced material include unidirectional materials, cloths, non-woven fabrics, wool, mats, and short fibers (cut fibers and milled fibers), and the form can be appropriately selected depending on the use. Examples of the fiber-reinforced material include glass fibers such as E-glass, C-glass, S-glass, NE-glass, and T-glass; and carbon fibers, aramid fibers, boron fibers, alumina fibers, and silicone carbide fibers. These materials may be used alone or in combination of two or more thereof. In addition, two or more materials may be hybridized. The fiber-reinforced material is preferably an inorganic material and is preferably a glass cloth.

The back surface protective member can contain an auxiliary agent for providing flame retardant or weather resistance.

A specific example of the back surface protective member is a glass epoxy sheet composed of a glass cloth and an epoxy resin.

### [Production of Solar Cell Module]

A crystal silicon solar cell module as an embodiment of the solar cell module of the present invention can be produced through, for example, the following production steps (1) to (4).

(1) An electrode material 18 is electrically connected to adjacent solar cell 16.
(2) A front surface protective member 11, a sheet of sealing member 14 on the front surface protective member side, a solar cell 16, a sheet of sealing member 15 on the back surface protective member side, and a back surface protective member 17 are laminated to form a laminate.
(3) The laminate is heated in vacuum and pressed to give a solar cell module 10.
(4) The solar cell module 10 is subjected to product inspection.

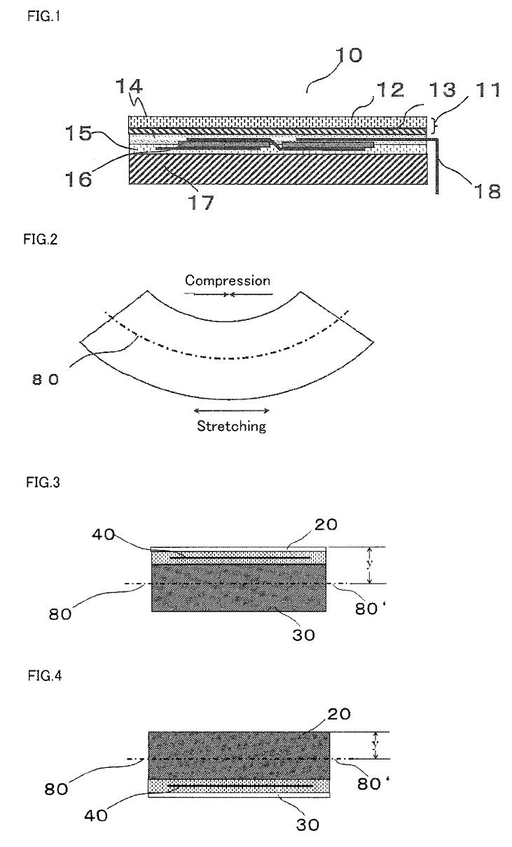

In the solar cell module of the present invention, the solar cell is preferably disposed on the front surface protective member side than the neutral plane of the solar cell module, from the viewpoint of resistance to the impact applied from the front surface protective member side. The term “neutral plane” refers to a plane that does not generate a tensile stress and a compressive stress and does not receive a load, when a stress is applied from one face of a sheet. FIG. 2 schematically illustrates a state when a stress is applied to a sheet from the upper side of the drawing (paper) toward the lower side. The alternate long and short dash line shows the neutral plane 80. The line of intersection between a cross section of the solar cell module and the neutral plane 80 is the “neutral axis”, and the neutral plane 80 can be determined by determining the neutral axis in each cross section.

According to the composite beam theory of material mechanics, in a composite beam composed of a plurality of materials having different moduli of elasticity, such as a laminate, the distance y from the reference line of the composite beam to the neutral axis is denoted by Expression (1). That is, when the upper side of a composite beam is defined as the reference line, y is the distance from the upper side.

γ=ΣEiBi/ΣEiAi (1)

The symbols in Expression (1) are as follows:

Ei: bending elastic modulus of the member of the i'th layer,

Bi: first moment of area of the member of the i'th layer, and

Ai: cross-sectional area of the member of the i'th layer.

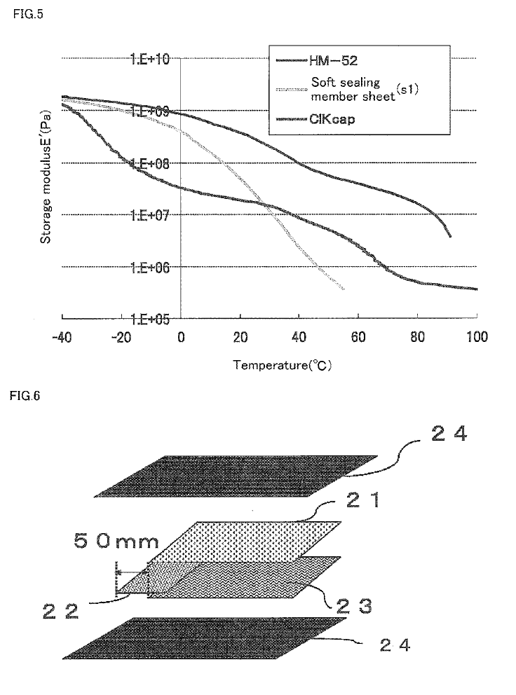

When a stress is applied to a solar cell module as a laminate composed of a plurality of materials from the normal direction to the front surface, a neutral plane exists inside the solar cell module. FIG. 3 shows a state of the presence of a solar cell on the front surface protective member side with respect to the position of the neutral plane 80 of the solar cell module. The solar cell receives a compression stress by application of a stress from the front surface protective member side of the solar cell module. FIG. 4 shows a state of the presence of a solar cell on the back surface protective member side with respect to the position of the neutral plane 80 of the solar cell module. The solar cell receives a tensile stress by application of a stress from the front surface protective member side of the solar cell module.

In the solar cell module of the present invention, the solar cell is preferably disposed on the front surface protective member side than the neutral plane of the solar cell module, in the light of preventing the solar cell module from warping.

From the viewpoint of a reduction in weight, an improvement in durability, and a reduction in manufacturing cost of the solar cell module, the solar cell module of the present invention is preferably composed of a front surface protective member using the solar cell protective sheet of the present invention; a sealing member mainly including at least one selected from ethylene-unsaturated carboxylic acid copolymers and ionomers of ethylene-unsaturated carboxylic acid copolymers and disposed on the front surface protective member side; a solar cell; a sealing member on the back surface protective member side; and a back surface protective member, which are bonded in this order.

### EXAMPLES

The present invention will now be described by examples. Note that “part(s)” and “%” used below mean “part(s) by mass” and “mass %”, respectively. Methods of evaluation and production examples will be described in advance of examples. As methods of evaluation, methods of [1] Evaluation of members of solar cell module and [2] Evaluation of solar cell module will be described. As production examples, [Production Example 1] an example of producing a soft sealing member sheet, [Production Example 2] an example of producing a dispersant, and [Production Examples 3 to 6] examples of producing methacrylic polymers p1 to p4 having functional groups reactive with carboxyl groups will be described.

### [1] Evaluation of Members of Solar Cell Module

### [1-1] Average Linear Expansion Coefficient

The average linear expansion coefficients of the front surface protective member and the back surface protective member are measured with a thermomechanical analyzer (trade name: Thermo Plus TMA8310, manufactured by Rigaku Corporation). A measurement sample having a length of 15 mm and a width of 5 mm is heated at a temperature-increasing rate of 5° C./min, and the sample lengths in the length direction and the width direction are measured at 20° C. and 25° C. The degree of expansion of the holder is corrected using a quartz reference sample. The linear expansion coefficients in the length direction and the width direction are calculated by the following Expression (2), and the arithmetic mean value is used as the average linear expansion coefficient.

Linear expansion coefficient=(1/Lₜ₁)×(Lₜ₂−Lₜ₁)/(t₂−t₁) (2)

Lₜ₁: sample length (mm) at 20° C.

Lₜ₂: sample length (mm) at 25° C.

t₂: 25(° C.),

t₁: 20(° C.)

### [1-2] Storage Modulus

The storage modulus (unit: MPa) of a sealing member is measured with a viscoelasticity measuring apparatus (trade name: EXSTAR DMS6100, manufactured by SII Nano Technology Inc.). The sealing material is first heat-pressed at 135° C. or 150° C. to produce a sheet having a thickness of 0.9 mm. The sheet is cut into test pieces having a width of 5 mm and a length of 50 mm. Subsequently, the storage moduli are measured within a temperature range of 20° C. to 40° C. under the following conditions, and the maximum and minimum storage moduli are determined.

### <Measurement Conditions>

Deformation mode: tensile measurement

Frequency: 1 Hz

Measurement temperature: −50° C. to 200° C.

Temperature-increasing rate: 2° C./min

### [1-3] Adhesiveness of Solar Cell Protective Sheet

In this evaluation, the adhesion between the front surface protective member (solar cell protective sheet) and the sealing member is evaluated.

### (1) Production of Test Piece for Adhesiveness Evaluation

Sheet pieces or film pieces having the following sizes (length×width) are prepared.

Solar cell protective sheet piece: 200 mm×200 mm

Sealing member sheet piece: 200 mm×200 mm

PET film piece: 60 mm×200 mm

As shown in FIG. 6, a laminate L₁ having a PET film piece 22 between a solar cell protective sheet piece 21 and a sealing member sheet piece 23 is prepared. On this occasion, the solar cell protective sheet piece 21 is disposed such that the adhesive layer of the solar cell protective sheet piece 21 faces the lower side and becomes in contact with the sealing member sheet piece 23 and the PET film piece 22. The PET film piece is disposed such that 50 mm of the length of 60 mm (a portion by 50 mm from the left side in FIG. 6) does not overlap the laminate portion of the solar cell protective sheet piece 21 and the sealing member sheet piece 23.

Subsequently, as shown in FIG. 6, this laminate L₁ is disposed between two mold releasing glass cloth sheets 24 of 500 mm×500 mm (trade name: Honda flow fabric, manufactured by Honda Sangyo Co., Ltd.) such that the laminate L₁ does not protrude from the glass cloth sheets 24 to give laminate L₂.

The laminate L₂ is placed on the hot plate of a solar cell module laminator (trade name: LM-50X50-S, manufactured by NPC Incorporated) and is pressure-bonded at 150° C. for 15 minutes in a vacuum of 10.3 kPa to give a laminate L₃. Subsequently, the two glass cloth sheets 24 are peeled off from the laminate L₃ to give a laminate L₄. Subsequently, strip-shaped test pieces L₅ having a length of 250 mm and a width of 15 mm for adhesiveness evaluation are prepared from the laminate L₄.

### (2) Evaluation of Adhesiveness

The whole surface of the test piece is fixed to the test piece-fixing place of an instron tensile tester (trade name: 5567, manufactured by Instron Japan Co., Ltd.) such that the sealing member sheet piece of the test piece is the upper side. Subsequently, the edge of the PET film piece 22 of the test piece is clamped by clips. Subsequently, the adhesive strength between the solar cell protective sheet piece and the sealing member sheet piece is measured by pulling the clips at a peel angle of 180° and a tensile speed of 200 mm/min. The adhesion between the solar cell protective sheet and the sealing member is evaluated by the following criteria:

A: good adhesion with an adhesive strength of 8 N/15 mm or more and less than 15 N/15 mm,

B: slightly low adhesion with an adhesive strength of 5 N/15 mm or more and less than 8 N/15 mm, and

C: low adhesion with an adhesive strength of 0 N/15 mm or more and less than 5 N/15 mm.

### [2] Evaluation of Solar Cell Module

The solar cell module is subjected to an impact resistance test, a temperature cycling test, and a high-temperature and high-humidity test shown below. The appearance, the presence or absence of cracking, and the power generation characteristics shown below are evaluated in each test.

### [2-1] Impact Resistance Test

In the impact resistance test, a set of the solar cell module is installed on the jig of a drop weight tester, and a steel ball having a mass of 227±2 g and a diameter of 38 mm is freely dropped from a height of 1 m to the central point of the cover glass.

### (1) Evaluation of Appearance

The solar cell module after the test is inspected by visual observation whether the solar cell has cracking or wrinkles, and the appearance is evaluated by the following criteria:

Rank A: no cracking, wrinkles, and warping is observed in the solar cell, and

Rank B: at least one of cracking, wrinkles, and warping is observed in the solar cell.

### (2) Evaluation of the Presence or Absence of Cracking

The solar cell module after the test is set on the sample table of a solar cell EL photographing device (trade name: PVX100, manufactured by ITES Co., Ltd.). Subsequently, the solar cell module is connected to an electrode and is then electrified. The surface of the solar cell is photographed, and the presence or absence of cracking is evaluated by the following criteria:

Rank A: substantially no dents at the point of fall of the steel ball, no cracks around the point, and no circular cracks that are conceived due to the deformation of the whole module caused by the fall of the steel ball are observed, and

Rank B: a large number of dents at the point of fall of the steel ball, cracks around the point, and circular cracks that are conceived due to the deformation of the whole module caused by the fall of the steel ball are observed.

### (3) Evaluation of Power Generation Characteristics

The maximum electric power P1 of the solar cell module before the test and the maximum electric power P2 of the solar cell module after the test are measured with a solar simulator (trade name: NMT-50x50-20MS, manufactured by NPC Incorporated) at 25° C. and a strength of 1,000 W/m². The reduction rate of the maximum electric power [100(P1−P2)/P1] (%) is calculated from the measured values. The power generation characteristics are evaluated by the following criteria:

Rank A: a reduction rate of the maximum electric power of 5% or less, and

Rank B: a reduction rate of the maximum electric power of higher than 5%.

### [2-2] Temperature Cycling Test

The temperature cycling test is performed as follows. A set of the solar cell module is left to stand at −40° C. for 10 minutes, is then heated up to 85° C., and is left to stand for 10 minutes. Subsequently, the solar cell module is cooled down to −40° C. and is left to stand for 10 minutes. The cycle described above is repeated for 50 cycles.

The methods of evaluation are the same as those described in the paragraph [2-1] except that the evaluation criteria in (2) Evaluation of the presence or absence of cracking in the solar cell surface are as follows:

Rank A: no cracking is observed in the solar cell, and

Rank B: cracking is observed in the solar cell.

### [2-3] High-Temperature and High-Humidity Test

The high-temperature and high-humidity test is performed by leaving a set of the solar cell module to stand at a temperature of 85° C. and a relative humidity of 85% for 1,000 hours. The methods of evaluating the appearance, the presence or absence of cracking, and the power generation characteristics are the same as those in the paragraph [2-2].

### Production Example 1

A syrup was prepared by dissolving 25 parts of an acrylic copolymer powder (trade name: BR-107, BMA/MMA=60:40, Mw=60,000, manufactured by Mitsubishi Rayon Co., Ltd.) in a mixture of 25 parts of methyl methacrylate (containing 2.5 ppm of polymerization inhibitor, manufactured by Mitsubishi Rayon Co., Ltd.), 20 parts of n-butyl acrylate (manufactured by Tokyo Chemical Industry Co., Ltd.), and 30 parts of 2-ethylhexyloxy diethylene glycol acrylate (trade name: Aronix M120, manufactured by Toagosei Company, Limited). One part of Irgacure 184 (manufactured by Ciba Specialties Chemicals Corp.) serving as a polymerization initiator was dissolved in the syrup, and the dissolved oxygen in the syrup was removed by vacuum degassing. Separately, two sheets of polyethylene terephthalate (trade name: A4100, manufactured by Toyobo Co., Ltd., hereinafter referred to as “PET sheet”) were prepared.

The syrup was flow-coated onto one of the PET sheets, and another PET sheet was placed thereon, followed by adjusting the total thickness of the PET sheets and the flow-coated mixture therebetween to 0.5 mm. The monomer in the syrup was polymerized by irradiation with light using a chemical lamp showing a peak illumination intensity of 2.2 mW/cm² for 1 hour to give a soft sealing member sheet (s1) having a thickness of 450 μm. This soft sealing member sheet (s1) had low stickiness, so that in a rolling ball tack test, the ball did not stop on a plane inclined at 20 degrees, and was thus a sheet to be easily handled.

### Production Example 2

In a 1200-L reaction vessel equipped with a stirrer, a cooling tube, and a thermometer were placed 61.6 parts of 17% aqueous potassium hydroxide solution, 19.1 parts of methyl methacrylate (trade name: Acryester M, manufactured by Mitsubishi Rayon Co., Ltd.), and 19.3 parts of deionized water. Subsequently, the solution in the reaction vessel was stirred at room temperature until an exothermic peak was observed, and further stirred for 4 hours. The reaction solution in the reaction vessel was then cooled down to room temperature to give an aqueous potassium methacrylate solution.

Subsequently, in a 1050-L reaction vessel equipped with a stirrer, a cooling tube, and a thermometer were placed 900 parts of deionized water, 60 parts of sodium 2-sulfoethyl methacrylate (trade name: Acryester SEM-Na, manufactured by Mitsubishi Rayon Co., Ltd.), 10 parts of the above aqueous potassium methacrylate solution, and 12 parts of methyl methacrylate (trade name: Acryester M, manufactured by Mitsubishi Rayon Co., Ltd.), followed by stirring. The solution temperature was increased to 50° C., while replacing the air in the reaction vessel with nitrogen. To the reaction vessel was added 0.08 parts of 2,2′-azobis(2-methylpropionamidine)dihydrochloride (trade name: V-50, manufactured by Wako Pure Chemical Industries, Ltd.) as a polymerization initiator, and the solution temperature was further increased to 60° C. After the increase of the temperature, methyl methacrylate (trade name: Acryester M, manufactured by Mitsubishi Rayon Co., Ltd.) was continuously dropwise added to the reaction vessel at a rate of 0.24 drops/min for 75 minutes with a dropping pump. Subsequently, the solution in the reaction vessel was maintained at 60° C. for 6 hours with stirring, and was then cooled to room temperature (25° C.) to give a dispersant (dl) having a solid content of 10% as a transparent aqueous solution.

### Production Example 3

In a 10-L reaction vessel equipped with a stirrer, a reflux condenser, a thermometer, and a nitrogen gas inlet were placed 98 parts of methyl methacrylate (trade name: Acryester M, manufactured by Mitsubishi Rayon Co., Ltd.), 1 part of methyl acrylate (trade name: Methyl Acrylate, manufactured by Mitsubishi Chemical Corporation), 1 part of glycidyl methacrylate (trade name: Acryester G, manufactured by Mitsubishi Rayon Co., Ltd.), 0.5 parts of n-octyl mercaptan (manufactured by Wako Pure Chemical Industries, Ltd.) as a chain transfer agent, 0.5 parts of dilauroyl peroxide (trade name: Peroyl L, manufactured by NOF Corporation) as an initiator, and 200 parts of deionized water.

The air in the reaction vessel was sufficiently replaced with nitrogen gas, and 0.2 parts of dispersant (dl) and 0.3 parts of sodium sulfate (manufactured by Wako Pure Chemical Industries, Ltd.) were then added to the reaction vessel, while stirring the solution in the reaction vessel. Subsequently, the solution in the reaction vessel was heated up to 80° C. in a nitrogen gas flow to start suspension polymerization. After observation of the heat generation by polymerization, the solution temperature was increased to 95° C. and was further maintained at the temperature for 30 minutes to give a suspension containing a polymer.

This suspension was filtered through a nylon filter cloth having an opening of 45 μm. The residue was washed with deionized water, was then dehydrated, and was dried at 30° C. for 16 hours to give a methacrylic polymer (p1) including functional groups reactive with carboxyl groups. This methacrylic polymer (p1) had an Mw of 52,000 and a molecular weight distribution of 1.9. In the methacrylic polymer (p1), the content of the monomer unit including a functional group reactive with a carboxyl group was 0.7 mol %.

### Production Example 4

A methacrylic polymer (p2) including functional groups reactive with carboxyl groups was prepared as in Production Example 3 except that the amounts of methyl methacrylate, methyl acrylate, and glycidyl methacrylate were 94 parts, 1 part, and 5 parts, respectively. This methacrylic polymer (p2) had an Mw of 61,000 and a molecular weight distribution of 2.0.

### Production Example 5

A methacrylic polymer (p3) including functional groups reactive with carboxyl groups was prepared as in Production Example 3 except that the amounts of methyl methacrylate, methyl acrylate, and glycidyl methacrylate were 89 parts, 1 part, and 10 parts, respectively. This methacrylic polymer (p3) had an Mw of 51,000 and a molecular weight distribution of 2.0.

### Production Example 6

In a 10-L reaction vessel equipped with a stirrer, a reflux condenser, a thermometer, and a nitrogen gas inlet were placed 145 parts of deionized water, 0.1 parts of sodium sulfate (manufactured by Wako Pure Chemical Industries, Ltd.), and 0.5 parts of dispersant (dl), followed by stirring. Thus, an aqueous solution was prepared.

Subsequently, to the aqueous solution were added 80 parts of methyl methacrylate (trade name: Acryester M, manufactured by Mitsubishi Rayon Co., Ltd.), 20 parts of glycidyl methacrylate (trade name: Acryester G, manufactured by Mitsubishi Rayon Co., Ltd.), 1.9 parts of n-dodecyl mercaptan (manufactured by Wako Pure Chemical Industries, Ltd.) as a chain transfer agent, and 1.9 parts of lauroyl peroxide (manufactured by NOF Corporation) as a polymerization initiator. Thus, a dispersion was prepared.

The air in the reaction vessel was sufficiently replaced with nitrogen gas. The dispersion in the reaction vessel was heated to 70° C. with stirring for about 1.5 hours for reaction. The dispersion in the reaction vessel was further heated to 95° C. with stirring, was maintained at the temperature for 1 hour, and was then cooled to 30° C. to give a suspension containing a polymer.

This suspension was filtered through a nylon filter cloth having an opening of 45 μm. The residue was washed with deionized water, was then dehydrated, and was dried at 30° C. for 16 hours to give a methacrylic polymer (p4) including functional groups reactive with carboxyl groups. This methacrylic polymer (p4) had an Mw of 15,000 and a molecular weight distribution of 2.5.

### Example 1

A polymer solution for an adhesive layer having a solid concentration of 15% was prepared by mixing 15 parts of the methacrylic polymer (p1), 25.5 parts of toluene, and 59.5 parts of MEK. Subsequently, the resulting polymer solution for an adhesive layer was applied to one surface of an acrylic resin film (trade name: HBS006, manufactured by Mitsubishi Rayon Co., Ltd.) having a thickness of 125 μm at a rate of 6 mm/sec to give an application thickness of 12 μm with a bar coater (trade name: K303 Control Coater, manufactured by Matsuo Sangyo Co., Ltd.). The resulting laminate was dried at 80° C. for 10 minutes to give a solar cell protective sheet composed of a transparent resin sheet and an adhesive layer (b1) having a thickness of 2 μm laminated on a surface of the resin sheet.

A solar cell protective sheet piece having a length of 200 mm and a width of 200 mm was produced from the solar cell protective sheet. Separately, a sealing member sheet piece having a length of 200 mm and a width of 200 mm was produced from a sheet of an ionomer of an ethylene-unsaturated carboxylic acid copolymer (trade name: HM-52, manufactured by Tamapoly Co., Ltd.) having a thickness of 450 μm. A PET film piece having a length of 200 mm and a width of 60 mm was also produced from a PET film (trade name: A4100, manufactured by Toyobo Co., Ltd.) having a thickness of 100 μm.

These sheet and film pieces were produced into test pieces for evaluation of adhesiveness in accordance with the description in the paragraph [1-3] and were used for evaluation of adhesiveness of the solar cell protective sheets. The adhesiveness was satisfactory. The results are shown in Table 1. The compounds and materials represented by abbreviations in Table 1 are shown in Table 2.

### Examples 2 and 3

Solar cell protective sheets including the adhesive layer (b2) or (b3) were prepared as in Example 1 except that the methacrylic polymer including functional groups reactive with carboxyl groups used were those shown in Table 1 and were evaluated for adhesiveness. The evaluation results are shown in Table 1.

### Example 4

As the polymer for an adhesive layer, a mixture of 7.5 parts of the methacrylic polymer (p4) and 7.5 parts of acrylic resin beads (trade name: Dianal BR-80, manufactured by Mitsubishi Rayon Co., Ltd.) serving as a binder resin was used instead of 15 parts of the methacrylic polymer (p1). A solar cell protective sheet including an adhesive layer (b4) was prepared as in Example 1 except the above, and was evaluated for adhesiveness. The evaluation results are shown in Table 1. The content of the monomer unit b including a functional group reactive with a carboxyl group was 7.2 mol % based on the total mass of the polymer constituting the adhesive layer.

### Comparative Example 1

A polymer solution for an adhesive layer having a solid concentration of 10% was prepared by mixing 10 parts of an olefin polymer (trade name: LOTADER AX-8900, manufactured by Arkema K.K.) including functional groups reactive with carboxyl groups in the adhesive layer, 27 parts of toluene, and 63 parts of MEK.

Subsequently, a solar cell protective sheet including an adhesive layer (b5) was prepared as in Example 1 except that the polymer solution for an adhesive layer prepared above was used and was evaluated for adhesiveness. The evaluation results are shown in Table 1. Since an olefin polymer including functional groups reactive with carboxyl groups was used as the adhesive layer, the solar cell protective sheet had poor adhesiveness.

### Comparative Example 2

In this Comparative Example, an acrylic resin film not including an adhesive layer was used as the solar cell protective sheet. An acrylic resin film (trade name: HBS006, manufactured by Mitsubishi Rayon Co., Ltd.) was cut into a film having a length of 200 mm and a width of 200 mm as a solar cell protective sheet to produce a test piece for evaluation of adhesiveness.

Except the above, the adhesiveness of the solar cell protective sheet was evaluated as in Example 1. The evaluation results are shown in Table 1. Since the solar cell protective sheet and the sealing member were laminated without having an adhesive layer therebetween, the solar cell protective sheet had poor adhesiveness.

### Comparative Example 3

In this Comparative Example, a PET film not including an adhesive layer was used as the solar cell protective sheet. A test piece for evaluation of adhesiveness was produced from a PET film (trade name: A4100, manufactured by Toyobo Co., Ltd.) having a thickness of 100 μm as the solar cell protective sheet. Except the above, the adhesiveness of the solar cell protective sheet was evaluated as in Example 1. The evaluation results are shown in Table 1. Since the solar cell protective sheet did not have an adhesive layer, the adhesiveness thereof was poor.

TABLE 1

| | | | | | | | Comparative | Comparative | Comparative |
|---|---|---|---|---|---|---|---|---|---|
| | | | Example 1 | Example 2 | Example 3 | Example 4 | Example 1 | Example 2 | Example 3 |
| Adhesive | Type of adhesive layer | | (b1) | (b2) | (b3) | (b4) | (b5) | — | — |
| layer | (Meth)acrylic | Type | (p1) | (p2) | (p3) | (p4) | — | — | — |
| | polymer B | Content(part) | 15 | 15 | 15 | 7.5 | — | — | — |

| | | | | | | | | |
|---|---|---|---|---|---|---|---|---|
| Monomer | MMA(part) | 98 | 94 | 89 | 80 | — | — | — |
| unit | MA(part) | 1 | 1 | 1 | — | — | — | — |
| composition | GMA(part) | 1 | 5 | 10 | 20 | — | — | — |

| | | | | | | | |
|---|---|---|---|---|---|---|---|
| Mw | 52,000 | 61,000 | 51,000 | 15,000 | — | — | — |
| Molecular weight distribution | 1.9 | 2 | 2 | 2.5 | — | — | — |

| | | | | | | | | |
|---|---|---|---|---|---|---|---|---|
| Olefin polymer | AX-8900 | — | — | — | — | 10 | — | — |
| | (part) | | | | | | | |

| | | | | | | | | |
|---|---|---|---|---|---|---|---|---|
| Binder resin | Type | — | — | — | BR-80 | — | — | — |
| | Content(part) | — | — | — | 7.5 | — | — | — |
| | Mw | — | — | — | 100,000 | — | — | — |
| | Molecular weight distribution | — | — | — | 4.3 | — | — | — |
| | Tg(° C.) | — | — | — | 105 | — | — | — |

| | | | | | | | |
|---|---|---|---|---|---|---|---|
| Content of monomer unit b based on | 0.7 | 3.5 | 7.2 | 7.2 | 2.0 | 0 | 0 |
| total mass of polymer(mol %) | | | | | | | |

| | | | | | | | | |
|---|---|---|---|---|---|---|---|---|
| Type of front surface | Acrylic resin film | HBS006 | HBS006 | HBS006 | HBS006 | HBS006 | HBS006 | — |
| protective member | PET film | — | — | — | — | — | — | A4100 |

| | | | | | | | |
|---|---|---|---|---|---|---|---|
| Sealing member | HM-52 | HM-52 | HM-52 | HM-52 | HM-52 | HM-52 | HM-52 |
| Adhesiveness of solar cell protective sheet | A | A | A | B | C | C | C |

TABLE 2

| Abbreviation | Compound or material |
|---|---|
| MMA | Methyl methacrylate (Trade name: Acryester M, manufactured by |
| | Mitsubishi Rayon Co., Ltd.) |
| MA | Methyl acrylate (Trade name: Methyl Acrylate, manufactured by Mitsubishi |
| | Chemical Corporation) |
| GMA | Glycidyl methacrylate (Trade name: Acryester G, manufactured by |
| | Mitsubishi Rayon Co., Ltd.) |
| AX-8900 | Olefin polymer (Trade name: LOTADER AX-8900, manufactured by |
| | Arkema K.K.) |
| BR-80 | Acrylic resin beads (Trade name: Dianal BR-80, manufactured by |
| | Mitsubishi Rayon Co., Ltd.) |
| HBS006 | Acrylic resin film (Trade name:, manufactured by Mitsubishi Rayon Co., |
| | Ltd.) |
| A4100 | PET film (Trade name:, manufactured by Toyobo Co., Ltd.) |
| HM-52 | Sheet of ionomer of ethylene-unsaturated carboxylic acid copolymer |
| | (Trade name:, manufactured by Tamapoly Co., Ltd.) |
| MR-200 | Acrylic resin sheet (Trade name:, manufactured by Mitsubishi Rayon Co., |
| | Ltd.) |
| CIKcap | Ethylene-vinyl acetate copolymer (Trade name:, manufactured by C. I. |
| | Kasei Co., Ltd.) |
| ES-3230-J | Glass cloth base material-epoxy resin laminate sheet (Trade name: , |
| | manufactured by Risho Kogyo Co., Ltd.) |
| PTD250 | Back sheet (Trade name:, manufactured by MA Packaging Co., Ltd.) |

### Example 5

### 1. Production of Solar Cell Protective Sheet

A solar cell protective sheet composed of an acrylic resin film (trade name: HBS006, manufactured by Mitsubishi Rayon Co., Ltd.) having a thickness of 125 μm, which is a transparent resin sheet, and an adhesive layer (b4) having a thickness of 2 μm laminated on a surface of the acrylic resin film was produced as in Example 4.

### 2. Production of solar cell module

A front surface protective member (the above-described solar cell protective sheet), a sealing member, a solar cell, and a back surface protective member shown in Table 3 were prepared.

TABLE 3

| Member | Material |
|---|---|
| Front surface | 400 mm × 400 mm, one sheet |
| protective member | |
| (solar cell protective | |
| sheet) | |
| Sealing member sheet | Sheet of ionomer of ethylene-unsaturated |
| | carboxylic acid copolymer of 450 μm thickness |
| | (Trade name: HM-52, manufactured by Tamapoly |
| | Co., Ltd.), 400 mm × 400 mm, two sheets |
| Solar cell | Polycrystal cell of 0.2 mm thickness (trade name: |
| | Q6LTT-200/1520-A-D, manufactured by Q cells |
| | Japan Co., Ltd.) wired with electrode material, |
| | one sheet |
| Back surface | Glass cloth base material-epoxy resin |
| protective member | laminate sheet of 1.6 mm thickness (Trade |
| | name: ES3230-J, manufactured by Risho |
| | Kogyo Co., Ltd.), 400 mm × 400 mm, |
| | one sheet |

Subsequently, on the surface of the adhesive layer of the front surface protective member (solar cell protective sheet), the sealing member sheet, the solar cell, the sealing member sheet, and the back surface protective member were laminated in this order to prepare a laminate. This laminate was disposed between two mold releasing glass cloth sheets of 500 mm×500 mm (trade name: Honda flow fabric, manufactured by Honda Sangyo Co., Ltd.) to give a laminate composed of five layers.

The resulting laminate was placed on the hot plate of a solar cell module laminator (trade name: LM-50X50-S, manufactured by NPC Incorporated) and was pressure-bonded at 150° C. for 15 minutes in a vacuum of 10.3 kPa. Subsequently, the mold releasing glass cloth sheets were peeled off from this laminate to give a solar cell module. Similarly, three solar cell modules were produced in total.

### 3. Evaluation of Solar Cell Module

The solar cell modules prepared in above were evaluated in accordance with the above-described [2-1] Impact resistance test, [2-2] Temperature cycling test, and [2-3] High-temperature and high-humidity test. The evaluation results are shown in Table 4. The appearance and cracking evaluated after each test of the impact resistance test, the temperature cycling test, and the high-temperature and high-humidity test were all Rank A. In addition, the evaluation results of power generation characteristics were all Rank A, and the reduction rates of the maximum electric power were lower than the standard values specified in JIS (impact resistance test: not higher than 5%, temperature cycling test: not higher than 5%, high-temperature and high-humidity test: not higher than 10%).

### Comparative Example 4

As the front surface protective member, an acrylic resin film (trade name: HBS006, manufactured by Mitsubishi Rayon Co., Ltd.) was used instead of the solar cell protective sheet including the adhesive layer (b4); and as the sealing member, the soft sealing member sheet (s1) prepared in Production Example 1 was used. Except the above, a solar cell module was produced and evaluated as in Example 5. The evaluation results are shown in Table 4. Since the storage modulus of the sealing member was too low, the evaluation results were poor.

### Comparative Example 5

As the front surface protective member, an acrylic resin film (trade name: HBS006, manufactured by Mitsubishi Rayon Co., Ltd.) was used instead of the solar cell protective sheet including the adhesive layer (b4); and as the sealing member, an ethylene-vinyl acetate copolymer (trade name: CIKcap, manufactured by C. I. Kasei Co., Ltd.) was used. Except the above, a solar cell module was produced and evaluated as in Example 5. The evaluation results are shown in Table 4. Since the storage modulus of the sealing member was too low, cracking occurred in the impact resistance test, and the appearance in the high-temperature and high-humidity test was poor.

### Comparative Example 6

Semi-tempered glass for a solar cell (manufactured by AGC fabritech Co., Ltd.) was used as the front surface protective member; an ethylene-vinyl acetate copolymer (trade name: CIKcap, manufactured by C. I. Kasei Co., Ltd.) was used as the sealing member; and a back sheet (trade name: PTD250, manufactured by MA Packaging Co., Ltd.) was used as the back surface protective member. Except the above, a solar cell module was produced and evaluated as in Example 5. The evaluation results are shown in Table 4. Since the storage modulus of the sealing member was too low, cracking occurred in the impact resistance test, and the appearance in the high-temperature and high-humidity test was poor.

TABLE 4

| | | | | Comparative | Comparative | Comparative |
|---|---|---|---|---|---|---|
| | | | Example 5 | Example 4 | Example 5 | Example 6 |
| Front surface | Type | | HBS006 | HBS006 | HBS006 | Semi- |
| protective | | | | | | tempered |
| member | | | | | | glass |
| | Thickness(mm) | | 0.125 | 0.125 | 0.125 | 3.2 |
| Adhesive layer | Type | | (b4) | (b4) | — | — |
| Sealing member | Type | | HM-52 | Soft sealing | CIkcap | CIkcap |
| | | | | member | | |
| | | | | sheet(s1) | | |
| | Thickness(mm) | | 0.45 | 0.45 | 0.45 | 0.45 |
| | Storage | Minimum value | 103 | 2 | 9 | 9 |
| | modulus(Mpa) | Maximum value | 388 | 52 | 19 | 19 |
| Position of solar cell | | | Upper than | Upper than | Upper than | Lower than |
| | | | neutral plane | neutral plane | neutral plane | neutral plane |
| Back surface | Type | | ES-3230-J | ES-3230-J | ES-3230-J | PTD250 |
| protective | Thickness(mm) | | 1.6 | 1.6 | 1.6 | 0.3 |
| member | Average linear expansion | | 14 | 14 | 14 | 70 |
| | coefficient(ppm/° C.) | | | | | |
| | Mass per unit area(kg/m2) | | 2.8 | 2.8 | 2.8 | 1.4 |
| Initial appearance of module | | | A | A | A | A |
| Evaluation of | [2-1] | Appearance | A | B | A | A |
| solar cell | Impact | Cracking | A | B | B | B |
| module | resistance test | Power | A | B | A | A |
| | | generation | | | | |
| | | characteristics | | | | |
| | [2-2] | Appearance | A | B | A | A |
| | Temperature | Cracking | A | B | A | A |
| | cycling test | Power | A | B | A | A |
| | | generation | | | | |
| | | characteristics | | | | |
| | [2-3] | Appearance | A | B | B | B |
| | High- | Cracking | A | B | A | A |
| | temperature | Power | A | B | A | A |
| | and high- | generation | | | | |
| | humidity test | characteristics | | | | |

### EXPLANATION OF REFERENCE NUMERALS

10 solar cell module
11 front surface protective member
12 transparent resin sheet
13 adhesive layer
14 sealing member
15 sealing member
16 solar cell
17 back surface protective member
18 electrode material
20 front surface protective member
21 solar cell protective sheet piece
22 PET film piece
23 sealing member sheet piece
24 mold releasing glass cloth sheet
30 back surface protective member
40 solar cell
80 neutral plane

### INDUSTRIAL APPLICABILITY

The solar cell module of the present invention can be applied to, for example, domestic solar photovoltaic systems, on-vehicle solar photovoltaic systems, and industrial solar photovoltaic systems.

1. A solar cell module comprising:
a solar cell;
a sealing member embedding the solar cell therein;
a front surface protective member; and
a back surface protective member,
wherein the sealing member has a storage modulus of 6×10⁷ Pa or more and 1×10⁹ Pa or less in a temperature range of 20° C. to 40° C.; and
the back surface protective member has an average linear expansion coefficient of 40 ppm/° C. or less, wherein the mean value linear expansion coefficient is the average of linear expansion coefficients in the length direction and the width direction when the temperature of the back surface protective member is changed from 20° C. to 25° C.

2. The solar cell module according to claim 1, wherein the front surface protective member and the sealing member are laminated via an adhesive layer containing a (meth)acrylic polymer including functional groups reactive with carboxyl groups therebetween.

3. The solar cell module according to claim 1, wherein the front surface protective member is a laminate composed of a transparent resin sheet made of at least one transparent resin material selected from (meth)acrylic resins, polycarbonate resins, and fluororesins and an adhesive layer comprising a (meth)acrylic polymer including functional groups reactive with carboxyl groups laminated on a surface of the transparent resin sheet.

4. The solar cell module according to claim 1, wherein the sealing member comprises a thermoplastic resin including an olefin unit and another copolymerizable monomer unit.

5. The solar cell module according to claim 4, wherein the olefin unit is an ethylene unit.

6. The solar cell module according to claim 1, wherein the back surface protective member has a mass per unit area of 6 kg/m′ or less.

7. The solar cell module according to claim 1, wherein the back surface protective member comprises a fiber-reinforced material.

8. The solar cell module according to claim 7, wherein the fiber-reinforced material is glass cloth.

9. The solar cell module according to claim 1, wherein the back surface protective member comprises a binder resin.

10. The solar cell module according to claim 9, wherein the binder resin is an epoxy resin.

11. The solar cell module according to claim 1, wherein the solar cell is disposed on the front surface protective member side than the neutral plane of the solar cell module.

12. A solar cell protective sheet comprising:
a transparent resin sheet made of at least one transparent resin material selected from (meth)acrylic resins, polycarbonate resins, and fluororesins; and
an adhesive layer comprising a (meth)acrylic polymer including functional groups reactive with carboxyl groups laminated on a surface of the transparent resin sheet.

13. The solar cell protective sheet according to claim 12, wherein the transparent resin sheet has a thickness of 0.03 mm or more and 0.6 mm or less.

14. The solar cell protective sheet according to claim 12, wherein the (meth)acrylic polymer including functional groups reactive with carboxyl groups comprises 0.5 mol % or more and 30 mol % or less of a monomer unit including a functional group reactive with a carboxyl group based on 100 mol % of the monomer unit of the whole polymer in the adhesive layer.

15. A solar cell module comprising:
a solar cell protective sheet according to claim 12;
a sealing member mainly composed of at least one selected from ethylene-unsaturated carboxylic acid copolymers and ionomers of ethylene-unsaturated carboxylic acid copolymers on the front surface protective member side;
a solar cell;
a sealing member on the back surface protective member side; and
a back surface protective member laminated in this order.
